(19) United States
(12) Patent Application Publication
(10) Pub. No.: US 2021/0318926 A1
(43) Pub. Date: Oct. 14, 2021

(54) IDENTIFYING CORRECTIVE ACTIONS BASED ON TELEMETRY DATA

(71) Applicant: Hewlett-Packard Development Company, L.P., Spring, TX (US)

(72) Inventors: Roberto Argenta Coutinho, Porto Alegre (BR); Franco Vieira e Souza, Porto Alegre (BR); Holisson Soares da Cunha, Porto Alegre (BR); Maikel Maciel Rönnau, Porto Alegre (BR); Alexandre da Silva Quadra, Porto Alegre (BR)

(73) Assignee: Hewlett-Packard Development Company, L.P., Spring, TX (US)

(21) Appl. No.: 17/262,289

(22) PCT Filed: Nov. 7, 2018
(86) PCT No.: PCT/US2018/059702

§ 371 Date: Jan. 22, 2021

(51) Int. Cl. G06F 11/07; G06F 30/20; G06F 11/34

(52) U.S. Cl. CPC G06F 11/0793; G06F 11/3409; G06F 11/0721; G06F 30/20

(57) ABSTRACT

An example of a computer-readable medium storing machine-readable instructions. The instructions may cause a processor to receive telemetry data regarding a computer system and apply a first model to the telemetry data. The instructions may cause the processor to determine a system grade of the computer system is below a predetermined value and identify a corrective action to apply to the computer system.

### BACKGROUND

Companies may own fleets of computers and assign computers to employees as they are hired. Computers may be replaced or repaired over time. In addition, employees may change job roles or otherwise change their requirements for a computer system over time. A fleet management application may be used to track the assignment of computers and maintenance over time.

### BRIEF DESCRIPTION OF THE DRAWINGS

Various examples will be described below referring to the following figures:

FIG. 1 shows a fleet management system coupled with a fleet of electronic devices across a network in accordance with various examples;

FIG. 2 shows a method of receiving telemetry data and identifying a corrective action in accordance with various examples;

FIG. 3 shows a method of receiving telemetry data and reassigning a computer system to a different user in accordance with various examples; and

FIG. 4 shows a method of receiving telemetry data, determining a trend over time, and identifying a corrective action in accordance with various examples.

### DETAILED DESCRIPTION

Managing a fleet of computers across a company may involve purchasing new computers, repairing or updating existing computers, and reassigning computers among users. Computer systems are composed of multiple components with various options. Size of memory, capacity of local drives, processor power, and battery life are some of the different attributes that may be changed. Providing a user with a computer system that is inadequate to the user's needs with regards to just one of those attributes can negatively affect the user's productivity. Conversely, providing a computer system to a user that is significantly more powerful than the user's needs may be a waste of resources.

Collecting telemetry data from the fleet of computers to analyze and determine the adequacy of a computer system to a user's needs may allow data-based management of the fleet. Disparities between the user's needs and the assigned computer system may be detected, and corrective action may be taken. The corrective action may include repairing or updating components of the computer system or assigning a different computer system to a user. The fleet of computers may thus be effectively managed based on empirical data.

In one example in accordance with the present disclosure, an apparatus is provided. The apparatus comprises a computer-readable medium to store machine-readable instructions that, when executed by a processor, cause the processor to: receive first and second telemetry data from a computer system, the first and second telemetry data relating to use of the computer system; apply a first model to the first telemetry data to produce a first grade; apply a second model to the second telemetry data to produce a second grade; produce a system grade based on the first grade and the second grade; determine that the system grade is below a predetermined system grade value; and identify a corrective action to apply to the computer system to improve the system grade based on the determination and the first grade.

In one example in accordance with the present disclosure, an apparatus is provided. The apparatus comprises a computer-readable medium to store machine-readable instructions that, when executed by a processor, cause the processor to: receive first telemetry data from a first computer system, the first telemetry data relating to use of the first computer system, wherein the first computer system is assigned to a first user; receive second telemetry data from a second computer system, the second telemetry data relating to use of the second computer system, wherein the second computer system is assigned to a second user; apply a model to the first telemetry data to produce a first grade; apply the model to the second telemetry data to produce a second grade; produce a first system grade based on the first grade; produce a second system grade based on the second grade; determine that the first system grade is below a predetermined system minimum grade value; determine that the second system grade is above a predetermined system maximum grade value; and reassign the first computer system to the second user based on the determinations.

In one example in accordance with the present disclosure, an apparatus is provided. The apparatus comprises a computer-readable medium to store machine-readable instructions that, when executed by a processor, cause the processor to: receive first telemetry data from a computer system, the first telemetry data relating to use of a component of the computer system at a first point in time; apply a model to the first telemetry data to produce a first grade; receive second telemetry data from the computer system, the second telemetry data relating to use of the component at a second point in time; apply the model to the second telemetry data to produce a second grade; determine a trend over time based on the first grade and the second grade; and identify a corrective action to apply to the computer system based on the trend.

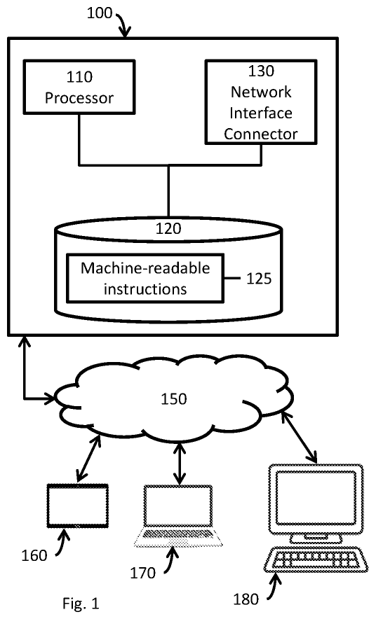

FIG. 1 shows a fleet management system 100 coupled with a fleet of electronic devices 160, 170, 180 across a network 150 in accordance with various examples. Fleet management system 100 may include a processor 110, a computer-readable medium 120, and a network interface connector 130. The computer-readable medium 120 may include machine-readable instructions 125 for execution by the processor 110. When executed by the processor 110, the machine-readable instructions 125 may cause the processor 110 to perform methods, such as the methods disclosed in connection with the other figures herein. The machine-readable instructions 125 may be part of an application installed on the fleet management system 100.

The fleet management system 100 may include a server, a laptop or desktop computer, a tablet, or another electronic device. The fleet management system 100 may be a distributed computer system composed of multiple electronic devices. The processor 110 may comprise a microprocessor, a microcomputer, a microcontroller, a field programmable gate array (FPGA), or discrete logic to execute machine-readable instructions. The computer-readable medium 120 may include a hard drive, solid state drive (SSD), flash memory, electrically erasable programmable read-only memory (EEPROM), or random access memory (RAM). The network interface connector 130 may couple the fleet management system 100 to the fleet of electronic devices 160, 170, 180 via a wired connection, such as an Ethernet cable or Universal Serial Bus (USB) or via a wireless connection, such as WiFi. The connection may be via a network 150, which may include the Internet. The fleet of electronic devices 160, 170, 180 may include a tablet 160, a laptop computer 170, a desktop computer 180, a server, and a cell phone.

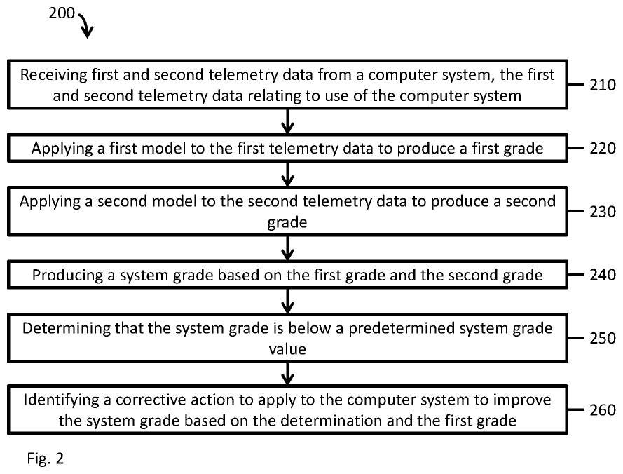

FIG. 2 shows a method 200 of receiving telemetry data and identifying a corrective action in accordance with various examples. The method 200 includes receiving first and second telemetry data from a computer system, the first and second telemetry data relating to use of the computer system (210). The method 200 includes applying a first model to the first telemetry data to produce a first grade (220). The method 200 includes applying a second model to the second telemetry data to produce a second grade (230). The method 200 includes producing a system grade based on the first grade and the second grade (240). The method 200 includes determining that the system grade is below a predetermined system grade value (250). The method 200 includes identifying a corrective action to apply to the computer system to improve the system grade based on the determination and the first grade (260).

Telemetry data includes data collected at a remote location. The telemetry data may be collected by a computer system, such as a tablet, a laptop computer, a desktop computer, a server, or a cell phone. The computer system may be part of a fleet of computer systems. The computer systems may be owned or leased by a company and assigned to users who are employees of that company. A user may be assigned multiple computer systems, such as a laptop computer, a desktop computer, and a cell phone.

In various examples, the telemetry data may relate to the use of the computer system that collects the data. The telemetry data may include information such as processor usage, memory usage, battery charge, total storage capacity, free storage capacity, applications running on the processor, and percent of processor capacity used by applications. The telemetry data may include settings or status of the computer system, such as an identification of the name and version of applications installed on the computer system, system settings, or user settings.

A model may be applied to the telemetry data to produce a grade. The model may be used to evaluate a particular aspect of the computer system, such as processing, memory, graphics, battery, or storage usage. Models are used to convert the telemetry data into a grade. Telemetry data may be converted into a grade through statistical methods, machine learning algorithms or various artificial intelligence techniques. An automated conversion may include describing the telemetry data, predicting future behavior, and fitting telemetry data to already known behaviors.

Some aspects may not be applicable to some computer systems, or they may receive a predetermined grade. For example, a desktop computer may not receive a battery grade, or it may receive a predetermined grade used to indicate no battery issues or that no battery is present. The grade may be different for different users of comparable computer systems. For example, one user may be a graphics designer and store a large number of high definition pictures on the computer's storage, while another user may be an executive assistant and store word processing documents. The computer system of the graphics designer may be graded to have insufficient storage space, while the executive assistant may be graded as having excessive storage space, as the total size of data stored on the computers may differ, even if the storage capacity is the same. The grade may be a numerical grade, such as a percentile. A higher grade may indicate that the computer system is resource limited in respect to that aspect, or that the user does not make full use of the available resources on the computer system. For some aspects, different grades may not be comparable as higher or lower, instead representing a state of the system. For example, one aspect may be an operating system grade, which indicates what operating system and its version are used on the computer system, or an applications package grade indicating a set of installed applications.

The grades may be combined to produce a system grade for the computer system. A high system grade means the system is generally meeting the user's usage, while a low system grade means the system is generally having difficulty satisfying a user's usage. A system grade may be a numerical grade with a low numerical value corresponding to a high system grade or a low system grade. Regardless of the numerical values used, a computer system that is more powerful than a user's usage receives a higher system grade, while a computer system that is having difficulty meeting a user's usage receives a lower system grade. In various examples, the grades may be numerical grades and the system grade is based on the mean value of the grades. The system grade may suggest whether or not the overall system is meeting the user's needs, even if one particular grade indicates a resource limitation. In producing the system grade, different grades may be given different weights. Different grades may also be weighted differently based on a user profile. For example, a graphics designer may have a user profile that weighs graphics processing and storage space more heavily than an executive assistant's user profile. The difference in weights may correspond to duties or responsibilities of an employment position.

The system grade may be used to identify computer systems for further analysis. In this way, the fleet management system may be able to prioritize the replacement or upgrading of computers based on the overall system grade. In various examples, a low individual grade may be weighted more heavily in producing the system grade. This may prevent overlooking computer systems that are grossly inadequate with regard to one aspect of use, but are otherwise more than adequate.

The fleet management system may identify a corrective action based on the system grade. A corrective action may include repairing or replacing a component of the computer system, reassigning the computer system to a different user, identifying a particular application causing problems, cleaning out a cache such as a web browser cache, deleting old or unused files such as emptying the recycle bin for deleted files, or modifying system or user settings. If a particular application is causing problems, the application may be uninstalled or updated to a new version. Identification of a particular application at issue may also be used to provide feedback to improve future versions of the application. System or user settings, such as a monitor resolution, accessibility options, or network or device configurations, may be modified.

In various examples, the computer system may be a laptop computer with a battery. Telemetry data regarding the battery and battery usage may be collected. Such data may include the total electrical capacity of the battery, the present amount of charge, what percentage of time the laptop is connected to a power outlet, and how often the laptop runs out of charge or goes below a certain charge level. Based on such telemetry data, the fleet management system may be able to determine that a laptop assigned to a user is almost always connected to a power outlet and rarely using the battery. The laptop may be replaced by a desktop computer with little to no negative effect on the user's productivity. Additional telemetry data, such as an assigned network identifier or another indication of location may be used. This may assist in differentiating between a laptop that always remains plugged in at the user's desk and a laptop that is routinely used at a home office, a main office, and satellite offices where power outlets are almost always available. Telemetry data for another laptop computer may indicate that the battery is regularly drained of all charge and rarely plugged in. The fleet management system may identify such a laptop for a potential battery replacement.

In various examples, a grade may correspond to a particular component or to a particular system. A grade may correspond to a battery, indicating when a battery needs to be repaired or replaced. A grade may correspond to a cooling system, indicating that fans or heat sinks may need to be repaired or replaced. One component may affect multiple grades. For example, random access memory (RAM) may affect a memory grade and also have an effect on a processor grade. Thus, repairing or replacing one component may affect multiple different grades.

The fleet management system may send a message to the computer system in response to identifying a corrective action. For example, a corrective action may involve updating the operating system or uninstalling an application. The message may be part of an automated process to make such corrections or allow systems administrators to remotely reconfigure the fleet of computers.

The corrective action may be to repair or replace a component, such as the RAM of a laptop computer. The fleet management system may submit a repair request for the computer system at issue. The repair requests may be handled by the fleet management system or some other system or application. The repair request may cause an appointment to be scheduled for a technician to perform the repair.

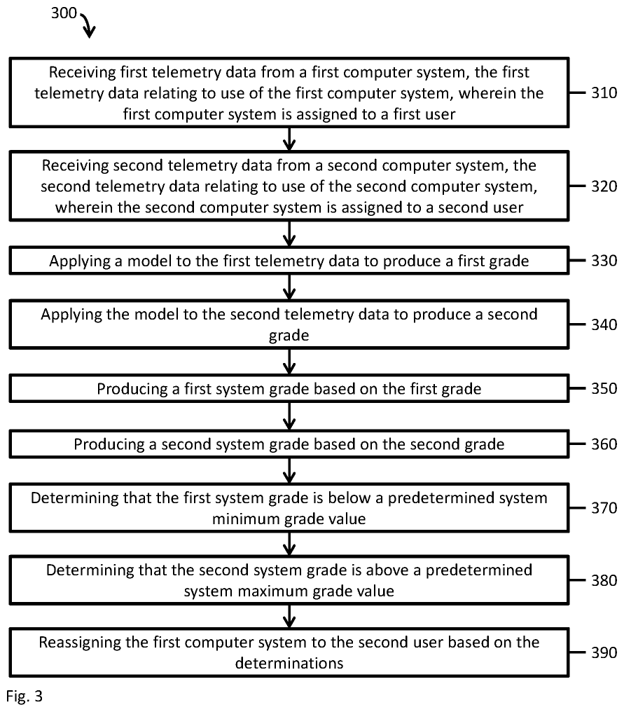

FIG. 3 shows a method 300 of receiving telemetry data and reassigning a computer system to a different user in accordance with various examples. The method 300 includes receiving first telemetry data from a first computer system, the first telemetry data relating to use of the first computer system, wherein the first computer system is assigned to a first user (310). The method 300 includes receiving second telemetry data from a second computer system, the second telemetry data relating to use of the second computer system, wherein the second computer system is assigned to a second user (320). The method 300 includes applying a model to the first telemetry data to produce a first grade (330). The method 300 includes applying the model to the second telemetry data to produce a second grade (340). The method 300 includes producing a first system grade based on the first grade (350). The method 300 includes producing a second system grade based on the second grade (360). The method 300 includes determining that the first system grade is below a predetermined system minimum grade value (370). The method 300 includes determining that the second system grade is above a predetermined system maximum grade value (380). The method 300 includes reassigning the first computer system to the second user based on the determinations (390).

A computer system may be assigned to a particular user. The grades and system grade may indicate that the computer system is operating normally, but that a first user is pushing the limits of some of the computer system's capabilities. The fleet management system may determine that the first user should be assigned a more powerful computer system. In contrast, a second user may be assigned a powerful computer system, but use it for word processing. The fleet management system may thus determine that the computer system being used by the first user has a system grade below a predetermined system minimum grade level, while the computer system being used by the second user has a system grade above a predetermined system maximum grade level. Being below the system minimum grade level may mean the computer system is inadequate to the user's needs. Being above the system maximum grade level may mean the computer system is much more powerful than the user's needs. The fleet management system may reassign the first user's computer system to the second user or the second user's computer system to the first user. Such reassignment of computer systems may result in a better match between a user's computer system needs and the assigned computer system.

In various examples, the fleet management system may determine that a computer system should be reassigned. As part of the reassignment, the fleet management system may also submit an upgrade request, based on the telemetry data. For example, the fleet management system may determine that reassignment of a computer system to a new user may better match the new user's needs, but that the storage should also be upgraded based on telemetry data regarding the user's storage use and present storage capacity of the computer system.

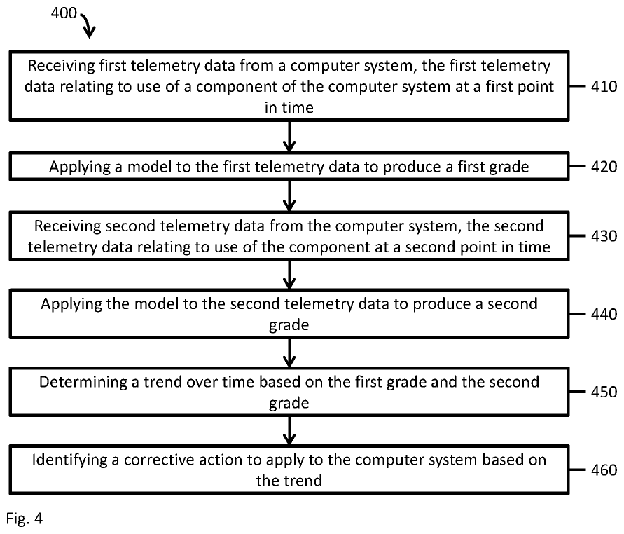

FIG. 4 shows a method of receiving telemetry data, determining a trend over time, and identifying a corrective action in accordance with various examples. The method 400 includes receiving first telemetry data from a computer system, the first telemetry data relating to use of a component of the computer system at a first point in time (410). The method 400 includes applying a model to the first telemetry data to produce a first grade (420). The method 400 includes receiving second telemetry data from the computer system, the second telemetry data relating to use of the component at a second point in time (430). The method 400 includes applying the model to the second telemetry data to produce a second grade (440). The method 400 includes determining a trend over time based on the first grade and the second grade (450). The method 400 includes identifying a corrective action to apply to the computer system based on the trend (460).

The fleet management system may collect telemetry data over time. The telemetry data may be used to identify a trend, which may indicate a deteriorating component or change in usage.

For example, a user may regularly work with lots of files, storing them on the computer system and then deleting them. The user may not empty the recycle bin of deleted files. The fleet management system could identify a trend in a storage grade over time. By noting the rate at which the grade deteriorates, a corrective action of emptying the recycling bin of deleted files may be identified, and a corresponding message sent to the computer system. This may quickly improve the storage grade, which then slowly degrades over time again. A change in the trend where the storage grade quickly degrades and quickly degrades again after emptying the recycling bin of deleted files may indicate another corrective action, such as replacing the storage with one of larger storage capacity, may be warranted. Other model grades, such as a gradually degrading thermal model or a gradually degrading battery model, may indicate that a particular component is failing, and the computer system should be scheduled for repair.

The fleet management system may include user profiles. The user profiles may identify the job responsibilities of a user. A user's job responsibilities may closely correspond to the type of computer system to be used. Software developers may need computers with more processing power. Graphics designers may need computers with more graphics power and storage capacity. The user profiles may assist the fleet management system in selecting an initial computer system to assign a user on being hired or to reassign a computer system when the user is promoted or changes business units. The fleet management system may receive a notification of such a role change and compare a default usage profile for the new role against available computer systems. The fleet management system may recommend a corrective action request based on this comparison, such as assigning the user a new or replacement computer system, or modifying components of the user's existing computer system.

In various examples, the fleet management system may not receive notification of a role change of a user. By analyzing trends in the grades and system grades, the fleet management system may identify a transition in the type of usage of the computer system. For example, a software developer may have been promoted to a software manager, which may use the computer system differently. Such a promotion may not have been entered into the fleet management system, but the fleet management system may still identify a transition for a user from a software developer usage profile to one of a software manager, and update the user profile accordingly. The fleet management system may request confirmation of such a profile change and may initiate a computer system reassignment based on such a profile change.

Collecting telemetry data and analyzing the computer usage of users based on the collected data allows an empirical evaluation of a company's fleet of computers and its assignment to employees. Rather than basing computer upgrades on scheduled upgrade or replacement cycles, upgrades, replacement, and reassignment of computers can occur in response to actual data indicative of actual use by the users. Mismatches between computer systems and the users may also be detected and existing computer systems reassigned to make better use of available resources. By matching users with appropriate computer systems, productivity can be increased without spending extra resources providing employees with overly powerful computer systems.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. A computer-readable medium to store machine-readable instructions that, when executed by a processor, cause the processor to:
receive first and second telemetry data from a computer system, the first and second telemetry data relating to use of the computer system;
apply a first model to the first telemetry data to produce a first grade;
apply a second model to the second telemetry data to produce a second grade;
produce a system grade based on the first grade and the second grade;
determine that the system grade is below a predetermined system grade value; and
identify a corrective action to apply to the computer system to improve the system grade based on the determination and the first grade.

2. The computer-readable medium of claim 1, wherein the computer system comprises a mobile computer and the first telemetry data comprises information regarding the amount of time the mobile computer is coupled to a power source external to the mobile computer.

3. The computer-readable medium of claim 1, wherein the first telemetry data corresponds to a first component of the computer system and the second telemetry data corresponds to a second component of the computer system.

4. The computer-readable medium of claim 1, wherein the machine-readable instructions, when executed by the processor, cause the processor to send a message to the computer system in response to the identification of the corrective action, the message to instruct the computer system to update an application on the computer system.

5. The computer-readable medium of claim 1, wherein the machine-readable instructions, when executed by the processor, cause the processor to submit a repair request for the computer system based on the identification of the corrective action.

6. A computer-readable medium to store machine-readable instructions that, when executed by a processor, cause the processor to:
receive first telemetry data from a first computer system, the first telemetry data relating to use of the first computer system, wherein the first computer system is assigned to a first user;
receive second telemetry data from a second computer system, the second telemetry data relating to use of the second computer system, wherein the second computer system is assigned to a second user;
apply a model to the first telemetry data to produce a first grade;
apply the model to the second telemetry data to produce a second grade;
produce a first system grade based on the first grade;
produce a second system grade based on the second grade;
determine that the first system grade is below a predetermined system minimum grade value;
determine that the second system grade is above a predetermined system maximum grade value; and
reassign the first computer system to the second user based on the determinations.

7. The computer-readable medium of claim 6, wherein the first computer system comprises a first processor, the first telemetry data includes a first processor usage value corresponding to the first processor, the second computer system comprises a second processor, and the second telemetry data includes a second processor usage value corresponding to the second processor.

8. The computer-readable medium of claim 6, wherein the first telemetry data includes a processor usage value corresponding to a processor of the first computer system and a memory usage value corresponding to a memory of the first computer system.

9. The computer-readable medium of claim 6, wherein the machine-readable instructions, when executed by the processor, cause the processor to:
receive third telemetry data from the first computer system, the third telemetry data relating to a component of the first computer system; and
submit an upgrade request to upgrade the component based on the reassignment of the first computer system and the third telemetry data.

10. The computer-readable medium of claim 6, wherein the machine-readable instructions, when executed by the processor, cause the processor to:
compare the second system grade with a usage profile corresponding to a third user; and
reassign the second computer system to the third user based on the comparison.

11. A computer-readable medium to store machine-readable instructions that, when executed by a processor, cause the processor to:
receive first telemetry data from a computer system, the first telemetry data relating to use of a component of the computer system at a first point in time;
apply a model to the first telemetry data to produce a first grade;
receive second telemetry data from the computer system, the second telemetry data relating to use of the component at a second point in time;
apply the model to the second telemetry data to produce a second grade;
determine a trend over time based on the first grade and the second grade; and
identify a corrective action to apply to the computer system based on the trend.

12. The computer-readable medium of claim 11, wherein the corrective action includes the uninstallation of an application from the computer system.

13. The computer-readable medium of claim 11, wherein the machine-readable instructions, when executed by the processor, cause the processor to:
identify a transition from a first usage profile to a second usage profile based on the trend; and
update a user profile based on the usage profile, the user profile corresponding to a user of the computer system, the identification of the corrective action request based on the second usage profile.

14. The computer-readable medium of claim 11, wherein the corrective action includes execution of a system scan on the computer system.

15. The computer-readable medium of claim 11, wherein the machine-readable instructions, when executed by the processor, cause the processor to:
receive a notification of a new role of a user of the computer system;
compare a usage profile corresponding to the new role with the second grade; and
recommend a second corrective action based on the comparison.
